(19) United States
(12) Patent Application Publication
(10) Pub. No.: US 2009/0321931 A1
(43) Pub. Date: Dec. 31, 2009

(54) Semiconductor device and method of manufacturing the same

(75) Inventors: Young-ho Lee, Seoul (KR); Jae-hwang Sim, Seoul (KR); Jae-Kwan Park, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/313,234

(22) Filed: Nov. 18, 2008

(30) Foreign Application Priority Data
Jun. 27, 2008 (KR) 10-2008-0061714

(51) Int. Cl. H01L 23/52

(52) U.S. Cl. 257/741; 257/E23.141

(57) ABSTRACT

A semiconductor device and a method of manufacturing the semiconductor device maintain an insulating distance between contact plugs and wiring lines formed on the contact plugs by using an etch mask pattern for forming contact holes. The device comprises a substrate comprising a plurality of conductive areas; an inter-layer insulating layer on the substrate having a plurality of contact holes through which the conductive areas are exposed; a first insulating layer covering the top surface of the inter-layer insulating layer; a plurality of contact plugs respectively connected to the plurality of conductive areas through the plurality of contact holes, the plurality of contact plugs having top surfaces a distance from each of which to a top surface of the substrate is less than a distance from the top surface of the inter-layer insulating layer to the top surface of the substrate; a plurality of ring-shaped insulating spacers covering inner sidewalls of the inter-layer insulating layer, inner sidewalls of the first insulating layer, and outer edge areas of top surfaces of the contact plugs so as to expose center areas of the top surfaces of the contact plugs in the contact holes; and a plurality of wiring lines above the first insulating layer and on the insulating spacers and respectively electrically connected to the plurality of contact plugs.

### CROSS-REFERENCE TO RELATED PATENT APPLICATION

This application claims the benefit of Korean Patent Application No. 10-2008-0061714, filed on Jun. 27, 2008, in the Korean Intellectual Property Office, the disclosure of which is incorporated herein in its entirety by reference.

### BACKGROUND OF THE INVENTION

1. Field of the Invention

Embodiments of the present invention relate to a semiconductor device having a fine pattern and a method of manufacturing the semiconductor device, and more particularly, to a semiconductor device having a fine pattern that includes wiring lines repeatedly formed with a fine pitch and contact plugs connecting the wiring lines to lower conductive areas and a method of manufacturing the semiconductor device.

2. Description of the Related Art

The ability to form fine patterns is essential to the manufacture of highly integrated semiconductor devices. In order to integrate an ever-increasing number of devices in a small area, the devices should be formed to be as small as possible. To this end, the pitch, which refers to the sum of the width of each pattern and a space between patterns, should be as small as possible. As the design rule of semiconductor devices continues to undergo drastic decrease, it is difficult to form patterns with a fine pitch by conventional photolithography methods, due to resolution limitations of the photolithography equipment and processes. In particular, when a plurality of contact plugs passing through an insulating layer are formed with a fine pitch and a plurality of wiring lines electrically connected to the contact plugs are formed with a fine pitch on the plurality of contact plugs in a small area in order to electrically connect unit devices formed on a substrate, the plurality of contact plugs and the plurality of wiring lines may be misaligned relative to each other. As a result, a wiring line may fail to be connected to a desired contact plug and a short-circuit, that is, an unwanted electrical connection between the wiring line and a contact plug other than the desired contact plug, may occur, thereby causing a “bridge” phenomenon.

During the manufacture a semiconductor memory device, contact plugs configured for connecting bit lines to active areas in a substrate are first formed, and then the bit lines are formed on the contact plugs to contact the contact plugs. Here, it is necessary to minimize the misalignment margin between the contact plugs and the bit lines. However, if a pitch between the bit lines is so reduced that a sufficient misalignment margin cannot be provided, it is difficult to form a layout that can obtain a minimum misalignment margin, reducing device yield and increasing manufacturing costs.

### SUMMARY OF THE INVENTION

Embodiments of the present invention provide a semiconductor device having a contact structure and a method of forming such a semiconductor device which can prevent a bridge phenomenon caused by a short-circuit that in the form of an unwanted electrical connection between a wiring line and a contact plug other than a desired contact plug. This is true even in a case where a plurality of wiring lines, which are repeatedly formed with a fine pitch and a plurality of contact plugs, which connect the wiring lines to lower conductive areas, are misaligned with each other while being electrically connected to each other. The device and method of forming such a de vice can also mitigate or prevent the adverse effects of parasitic capacitance that can occur between adjacent wiring lines.

In one aspect, a semiconductor device comprises a substrate comprising a plurality of conductive areas; an inter-layer insulating layer on the substrate having a plurality of contact holes through which the conductive areas are exposed; a first insulating layer covering the top surface of the inter-layer insulating layer; a plurality of contact plugs respectively connected to the plurality of conductive areas through the plurality of contact holes, the plurality of contact plugs having top surfaces a distance from each of which to a top surface of the substrate is less than a distance from the top surface of the inter-layer insulating layer to the top surface of the substrate; a plurality of ring-shaped insulating spacers covering inner sidewalls of the inter-layer insulating layer, inner sidewalls of the first insulating layer, and outer edge areas of top surfaces of the contact plugs so as to expose center areas of the top surfaces of the contact plugs in the contact holes; and a plurality of wiring lines above the first insulating layer and on the insulating spacers and respectively electrically connected to the plurality of contact plugs.

In one embodiment, each of the first insulating layer and the insulating spacers is formed of a material different than that of the inter-layer insulating layer.

In another embodiment, the first insulating layer and the insulating spacers are formed of the same material, and each are formed of a material different than that of the inter-layer insulating layer.

In another embodiment, the first insulating layer covers the top surface of the inter-layer insulating layer.

In another embodiment, the conductive areas are active areas formed on the substrate.

In another embodiment, the plurality of wiring lines are a plurality of bit lines that are repeatedly formed with a predetermined pitch and extend in parallel to one another.

In another embodiment, the plurality of wiring lines comprise a metal.

In another embodiment, the plurality of wiring lines comprise Cu.

In another aspect, a method of manufacturing a semiconductor device comprises: forming an inter-layer insulating layer on a semiconductor substrate comprising conductive areas; forming a hard mask pattern comprising a first insulating layer on the inter-layer insulating layer; forming a plurality of contact holes through which the conductive areas are exposed by etching the inter-layer insulating layer using the hard mask pattern as an etch mask; forming in the plurality of contact holes a plurality of contact plugs having top surfaces lower in height than a top surface of the inter-layer insulating layer so as to expose an upper portion of the inner sidewall of the inter-layer insulating layer in each of the contact holes; forming a plurality of ring-shaped insulating spacers covering inner sidewalls of the inter-layer of the insulating layer, inner sidewalls of the first insulating layer, and outer edge areas of the top surfaces of the contact plugs so as to expose center areas of the top surfaces of the contact plugs in the contact holes; and forming above the first insulating layer and on the insulating spacers a plurality of wiring lines that are respectively electrically connected to the plurality of contact plugs.

In one embodiment, the hard mask pattern comprises the first insulating layer and a protective layer covering the first insulating layer.

In another embodiment, the first insulating layer is a nitride layer, and the protective layer is an oxide layer.

In another embodiment, forming of the plurality of contact plugs comprises: forming a conductive layer filling the contact holes on a resultant structure including the hard mask pattern and the contact holes; removing part of the conductive layer so that the conductive layer remains only in the contact holes; and forming recesses at entrances of the plurality of contact holes by removing upper portions of the conductive layer so that an upper portion of a sidewall of the inter-layer insulating layer is exposed in each of the plurality of contact holes.

In another embodiment, removing of the part of the conductive layer so that the conductive layer remains only in the contact holes comprises etching the conductive layer using the hard mask pattern as an etch stop layer.

In another embodiment, the conductive layer comprises: a first barrier layer covering inner sidewalls of the contact holes; and a first conductive layer formed on the first barrier layer and filling the contact holes.

In another embodiment, forming of the recesses at the entrances of the plurality of contact holes by removing upper portions of the conductive layer comprises removing upper portions of the conductive layer using the first insulating layer of the hard mask pattern as an etch mask.

In another embodiment, forming of the plurality of insulating spacers comprises: forming a second insulating layer covering the first insulating layer, top surfaces of the contact plugs which are exposed through the recesses, and the sidewall of the inter-layer insulating layer; and removing part of the second insulating layer so as to expose part of the top surfaces of the contact plugs.

In another embodiment, each of the first insulating layer and the second insulating layer is formed of a material that is different than that of the inter-layer insulating layer.

In another embodiment, forming of the plurality of wiring lines comprises: forming a third insulating layer on the first insulating layer, the plurality of insulating spacers, and the plurality of contact plugs; forming on the first insulating layer and the plurality of insulating spacers an insulating mold pattern having spaces through which the top surfaces of the plurality of contact plugs are exposed by patterning the third insulating layer; and forming wiring lines in the spaces.

In another embodiment, the wiring lines are formed by electroplating.

In another embodiment, forming of the plurality of wiring lines comprises: forming a wiring line forming conductive layer on the first insulating layer, the plurality of insulating spacers, and the plurality of contact plugs; and forming on the first insulating layer and the plurality of insulating spacers the plurality of wiring lines that respectively contact the plurality of contact plugs by patterning the wiring line forming conductive layer.

### BRIEF DESCRIPTION OF THE DRAWINGS

The above and other features and advantages of the embodiments of the present invention will become more apparent by describing in detail exemplary embodiments thereof with reference to the attached drawings in which:

FIG. 1 is a partial plan layout of a wiring pattern of a semiconductor device, according to an embodiment of the present invention;

FIGS. 2A through 2K are cross-sectional views illustrating a method of manufacturing a semiconductor device, according to an embodiment of the present invention;

FIGS. 3A and 3B are cross-sectional views illustrating a method of manufacturing a semiconductor device, according to another embodiment of the present invention; and

FIG. 4 is a partial plan layout illustrating some elements of the semiconductor device manufactured by the method of FIGS. 2A through 2K.

### DETAILED DESCRIPTION OF EMBODIMENTS

Embodiments of the present invention will now be described more fully with reference to the accompanying drawings, in which exemplary embodiments of the invention are shown. The invention may, however, be embodied in many different forms and should not be construed as being limited to the embodiments set forth herein; rather these embodiments are provided so that this disclosure will be thorough and complete, and will fully convey the concept of the invention to those skilled in the art. In the drawings, the thicknesses of layers and regions are exaggerated for clarity, and like reference numerals denote like elements.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “bottom”, “lower”, “above”, “top”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only, and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein.

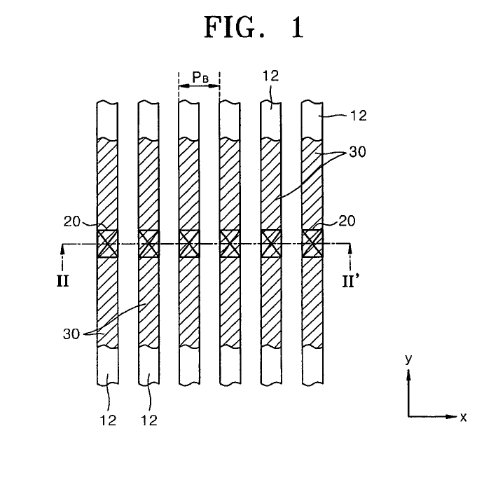

FIG. 1 is a partial plan layout of a wiring pattern of a semiconductor device, according to an embodiment of the present invention. In FIG. 1, a plurality of bit lines 30 included in a flash memory device are illustrated.

Referring to FIG. 1, the plurality of bit lines 30 are respectively formed on active areas 12 to have substantially the same width as that of the active areas 12, and extend in a first direction (y direction) parallel to a direction in which the active areas 12 extend. The bit lines 30 are electrically connected to the active areas 12 through a plurality of direct contacts 20, respectively. The bit lines 30 are repeatedly arranged with a predetermined pitch P_{B}. In FIG. 1, the plurality of direct contacts 20 are repeatedly formed with the same pitch as that of the plurality of bit lines 30. The plurality of direct contacts 20 are aligned in the second direction (x direction) perpendicular to the first direction. However, the present invention is not limited thereto and the direct contacts 20 may be aligned in a direction different from that shown in FIG. 1.

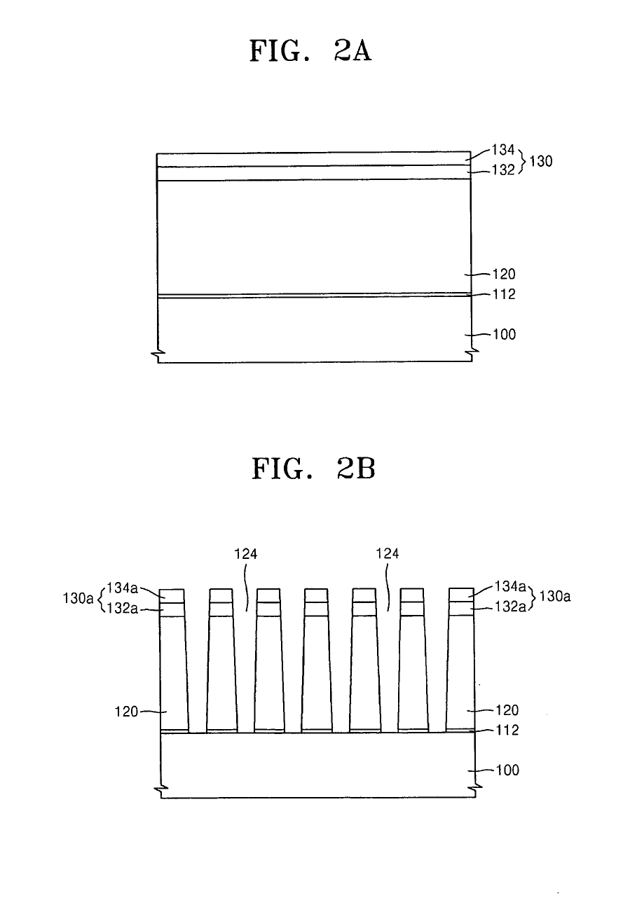

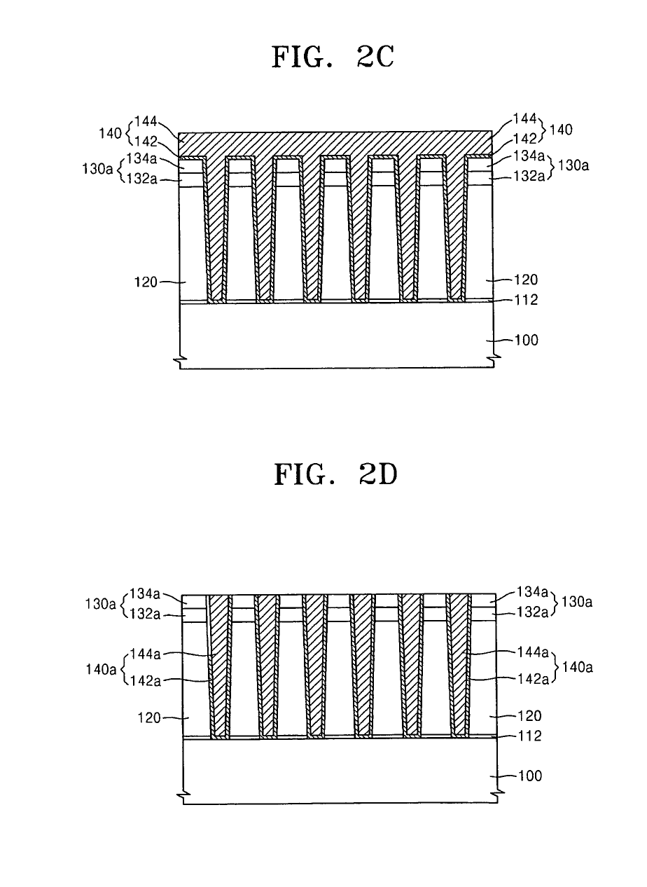

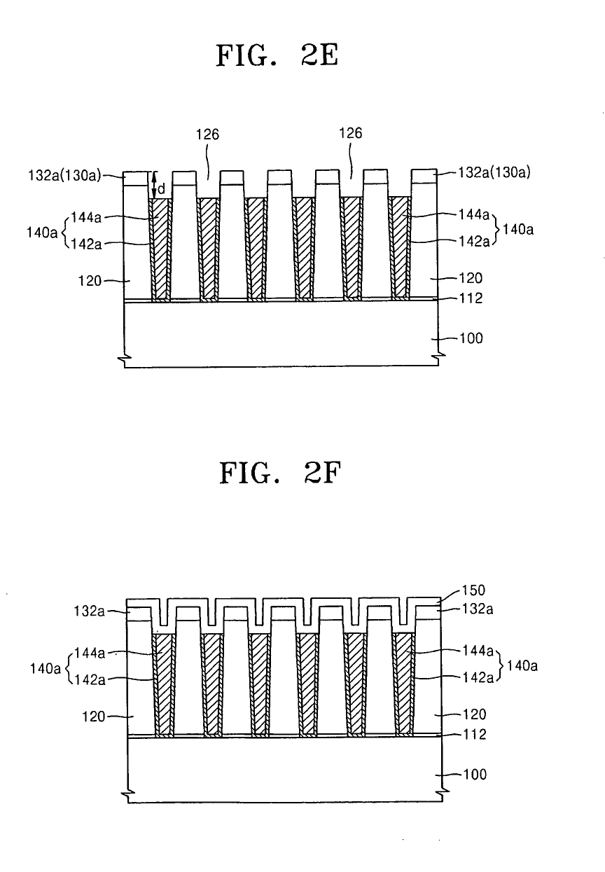

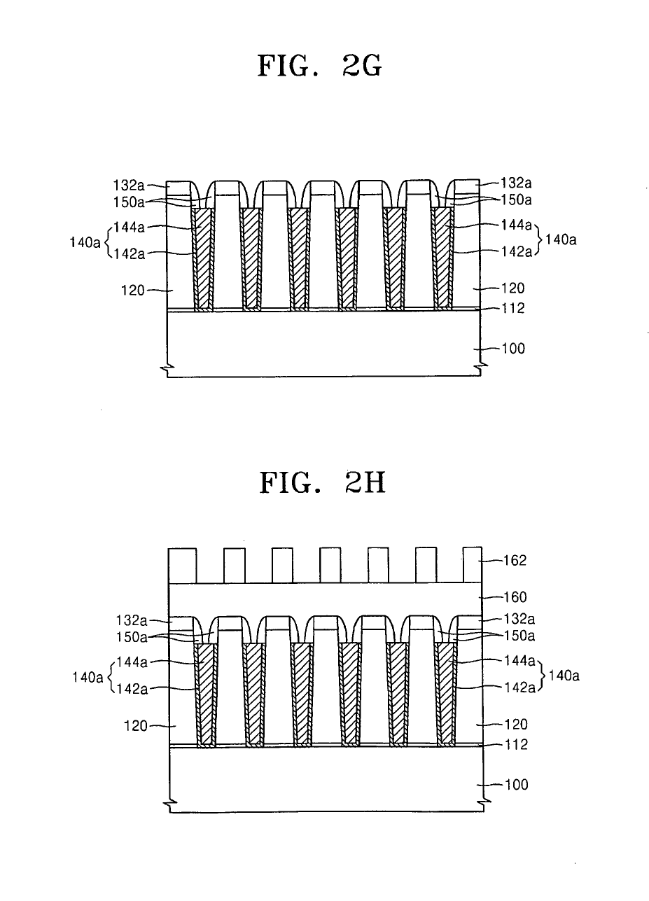

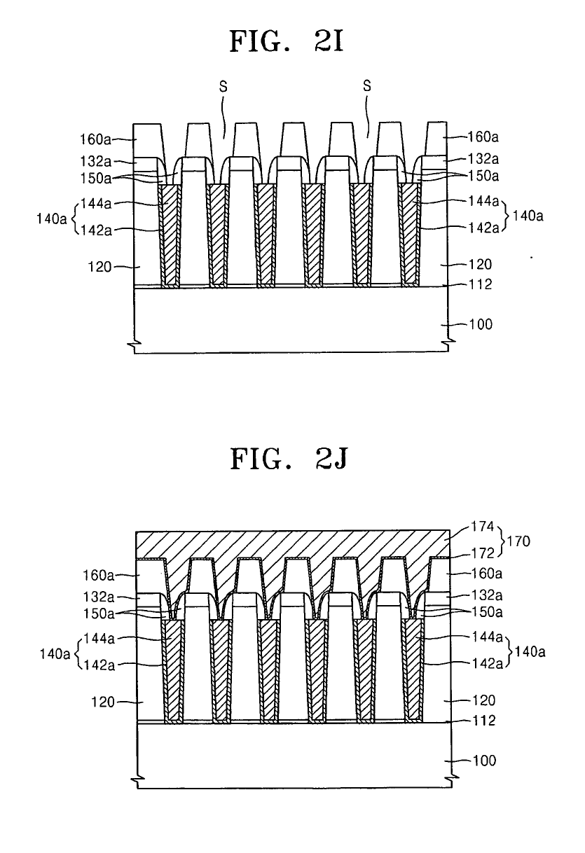

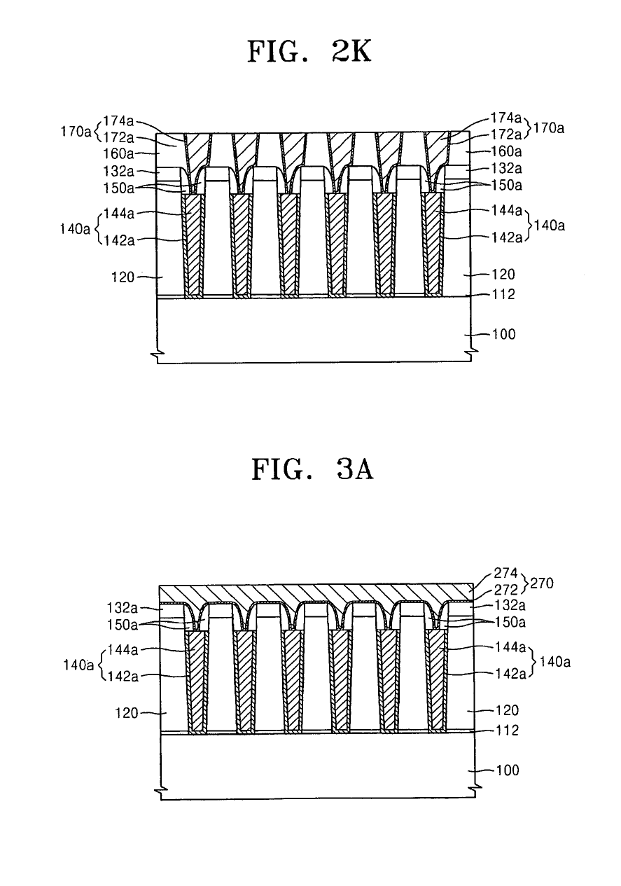

FIGS. 2A through 2K are cross-sectional views illustrating a method of manufacturing a semiconductor device, according to an embodiment of the present invention. In more detail, FIGS. 2A through 2K correspond to cross-sectional views taken along section line II-II′ of FIG. 1.

Referring to FIG. 2A, an etch stop insulating layer 112 and an inter-layer insulating layer 120 are sequentially formed on a semiconductor substrate 100 on which active areas (not shown) having the same layout as that of the active areas 12 of FIG. 1 are defined. A hard mask layer 130 is formed to entirely cover a top surface of the inter-layer insulating layer 120. The top surface of the interlayer insulating layer 120 is substantially parallel to an upper surface of the substrate 100. The hard mask layer 130 may include an etch mask layer 132 entirely covering the top surface of the inter-layer insulating layer 120 and a protective layer 134 entirely covering a top surface of the etch mask layer 132. The protective layer 134 is optional, and may be omitted.

Unit devices (not shown), which are necessary to form the semiconductor device, such as a plurality of word lines, may be formed in or on the semiconductor substrate 100, and the inter-layer insulating layer 120 may include a plurality of insulating layers covering the unit devices. Conductive areas (not shown), which may be electrically connected to the unit devices, may be exposed at or near a top surface of the semiconductor substrate 100.

The etch stop insulating layer 112 operates as an etch stop layer when the inter-layer insulating layer 120 is etched. The etch stop insulating layer 112 may be formed of a material having an etch selectivity that is different than that of the inter-layer insulating layer 120. According to the material of the inter-layer insulating layer 120, the etch stop insulating layer 112 may be a silicon nitride layer, a silicon oxide layer, a silicon oxide/nitride layer, or a silicon carbide layer.

The inter-layer insulating layer 120 may be formed of an insulating material having a relatively low dielectric constant so as to reduce resistance capacitance (RC) delay that is caused due to a coupling capacitance between bit lines as a space between neighboring bit lines is reduced. In various embodiments, the inter-layer insulating layer 120 can be formed, for example, of tetraethyl orthosilicate (TEOS), fluorine silicate glass (FSG), SiOC, or SiLK. The inter-layer insulating layer 120 can include at least one selected from the group consisting of a chemical vapor deposition (CVD) oxide layer, an undoped silicate glass (USG) layer, and a high density plasma (HDP) oxide layer.

The etch mask layer 132 constituting the hard mask layer 130 can comprise a single layer formed of a nitride, or a multi-layer including a nitride layer and an oxide layer which are sequentially stacked on each other. The protective layer 134 can comprise an oxide layer. Accordingly, the protective layer 134 operates as a buffer layer for preventing the etch mask layer 132 from being consumed during the manufacture of the semiconductor device. For example, if the inter-layer insulating layer 120 is an oxide layer, the etch mask layer 132 of the hard mask layer 130 may be a nitride layer and the protective layer 134 may be an oxide layer.

Referring to FIG. 2B, the hard mask layer 130 is patterned to form a hard mask pattern 130a including an etch mask pattern 132a and a protective pattern 134a. The hard mask layer 130 may be patterned using conventional photolithography processes. Next, the inter-layer insulating layer 120 is etched using the hard mask pattern 130a as an etch mask and the etch stop insulating layer 112 as an etch stop layer, to form a plurality of contact holes 124 through which the active areas of the semiconductor substrate 100 are exposed. The plurality of contact holes 124 may have substantially circular or rounded shapes when viewed from the top surface of the semiconductor substrate 100.

Referring to FIG. 2C, in the state where the top surface of the inter-layer insulating layer 120 is completely covered by the hard mask pattern 130a, especially, by the etch mask pattern 132a, a conductive material is deposited in the contact holes 124 and on the hard mask pattern 130a to form a conductive layer 140 filling the contact holes 124.

The conductive layer 140 can include a first barrier layer 142 covering inner walls of the contact holes 124 and a first conductive layer 144 formed on the first barrier layer 142 and filling the contact holes 124. The first barrier layer 142 can be formed of Ti, TiN, Ta, TaN, or a stack of at least two thereof. The first conductive layer 144 can be a metal layer or a polysilicon layer. For example, the first barrier layer 142 may be formed of Ti/TiN and the first conductive layer 144 can be formed of W.

Referring to FIG. 2D, an upper portion of the conductive layer 140 is removed from a top surface of the conductive layer 140 using the hard mask pattern 130a as an etch stop layer until a top surface of the hard mask pattern 130a is exposed, to form contact plugs 140a each including a first barrier pattern 142a and a first conductive pattern 144a remaining in the contact holes 124.

The upper portion of the conductive layer 140 can be removed, for example, by etch back or chemical mechanical polishing (CMP) to form the contact plugs 140a. While the part of the conductive layer 140 is removed, part of the protective pattern 134a covering the etch mask pattern 132a of the hard mask pattern 130a can be consumed. The etch mask pattern 132a is protected by the protective layer pattern 134a such that consumption of the etch mask pattern 132a is minimized or prevented while the part of the conductive layer 140 is removed.

Referring to FIG. 2E, upper portions of the contact plugs 140a are removed to a predetermined depth “d” from the top surface of the etch mask pattern 132a using the hard mask pattern 130a, especially, the etch mask pattern 132a, as an etch mask, such that the contact plugs 140a are recessed, or have a height that is lower than the top surface of the inter-layer insulating layer 120 at the upper entrances of the contact holes 124a. As a result, recess regions 126 through which top surfaces of the contact plugs 140a are exposed are present above the contact plugs 140a at the entrances of the contact holes 124. In one embodiment, the plurality of contact plugs 140a of FIG. 2E may correspond to the plurality of direct contacts 20 of FIG. 1.

While upper portions of the contact plugs 140a are removed to form the recess regions 126, part or all of the protective pattern 134a covering the etch mask pattern 132a may be consumed. In the illustration of FIG. 2E, the protective pattern 134a is shown as being completely consumed and the top surface of the etch mask pattern 132a is exposed.

When upper portions of the contact plugs 140a are etched to the predetermined depth “d” from the top surfaces of the contact plugs 140a in order to form the recess regions 126 above the contact plugs 140a in the contact holes 124, since the contact plugs 140a are etched using the etch mask pattern 132a as an etch mask, the contact plugs 140a can be sufficiently etched so as to ensure that portions of the first barrier pattern 142a are prevented from remaining on exposed sidewalls of the inter-layer insulating layer 120 in the recess regions 126.

Referring to FIG. 2F, an insulating layer 150 is formed on an entire surface of the resultant structure including the recess regions 126 so as to cover the inner sidewalls of the interlayer-insulating layer 120 which are exposed through the recess regions 126, the top surfaces of the contact plugs 140a, and sidewalls and top surfaces of the etch mask pattern 132a.

The insulating layer 150 can comprise, for example, a nitride layer or an oxide layer. The insulating layer 150 may be formed of the same material as that of the etch mask pattern 132a. For example, each of the etch mask pattern 132a and the insulating layer 150 may be a nitride layer.

Referring to FIG. 2G, the insulating layer 150 is etched back until central areas of the top surfaces of the contact plugs 140a are exposed, to form insulating spacers. 150a covering sidewalls of the inter-layer insulating layer 120 and the sidewall of the etch mask pattern 132a. The insulating spacers 150a have ring shapes and cover edge areas of the top surfaces of the contact plugs 140a so as to expose the central areas of the top surfaces of the contact plugs 140a.

Due to the presence of the insulating spacers 150a, an insulating distance as long as widths of the insulating spacers 150a can be maintained around the contact plugs 140a formed in the contact holes 124. Even in a case where the first barrier pattern 142a is not completely removed and remains in the recess regions 126 during etching of the upper portions of the contact plugs 140a in order to form the recess regions 126 (see FIG. 2E), the insulating spacers 150a can prevent a short-circuit from occurring between an adjacent conductive layer and the portion of the first barrier pattern 142a remaining in the recess regions 126.

Also, since the insulating spacers 150a are formed in the recess regions 126, the widths of the top surfaces of the contact plugs 140a which are exposed in the contact holes 124 is reduced and an insulating distance as long as the reduced width is maintained. Accordingly, even if misalignment occurs when a plurality of wiring lines respectively electrically connected to the plurality of contact plugs 140a are formed in a subsequent process, an insulating distance long enough to prevent a bridge phenomenon due to an unwanted electrical connection, or short-circuit, between a wiring line and a contact plug other than a desired contact plug can be maintained.

Referring to FIG. 2H, an insulating mold layer 160 is formed on a resultant structure including the insulating spacers 150a, and a fine mask pattern 162 through which portions of a top surface of the insulating mold layer 160 is exposed is formed on the insulating mold layer 160. The insulating mold layer 160 can comprise, for example, an oxide layer.

The fine mask pattern 162 is a negative pattern that is opposite a wiring line pattern that is to be formed on the contact plugs 140a. The fine mask pattern 162 may be formed by photolithography techniques or by a self-aligned double-patterning process that enhances feature density by doubling a pitch of a pattern formed by photolithography.

Referring to FIG. 2I, the insulating mold layer 160 is etched using the fine mask pattern 162 as an etch mask to form an insulating mold pattern 160a through which the top surfaces of the contact plugs 140a are exposed, and then the fine mask pattern 162 is removed. When the insulating mold layer 160 is etched, the etch mask pattern 132a and the insulating spacers 150a may be used as etch stop layers. Spaces S on which wiring lines are to be formed are defined in regions over the contact plugs 140a by the insulating mold pattern 160a.

In FIG. 2I, it is shown that the insulating mold pattern 160a can be obtained in case where the fine mask pattern 162 is misaligned relative to the plurality of contact plugs 140a of FIG. 2H. As shown in FIG. 2I, even when the fine mask pattern 162 is misaligned with the plurality of contact plugs 140a, a sufficient insulating margin can be provided between wiring lines to be formed between two neighboring contact plugs 140a due to presence of the insulating spacers 150a.

A process of forming a plurality of wiring lines by a damascene process on the contact plugs 140a that are exposed through the insulating mold pattern 160a will now be explained with reference to FIGS. 2J and 2K in detail.

Referring to FIG. 2J, a wiring layer 170 is formed on the top surfaces of the contact plugs 140a which are exposed through the insulating mold pattern 160a, sidewalls of the insulating spacers 150a, and an exposed surface of the insulating mold pattern 160a. The wiring layer 170 includes a second barrier layer 172 and a second conductive layer 174.

In order to form the wiring layer 170, the second barrier layer 172 is formed on the top surfaces of the contact plugs 140a which are exposed through the insulating mold pattern 160a, the sidewalls of the insulating spacers 150a, and the exposed surface of the insulating mold pattern 160a, and then the second conductive layer 174 filling the spaces S defined by the insulating mold pattern 160a is formed on the second barrier layer 172.

The second barrier layer 172 operates to prevent metal atoms of the second conductive layer 174 filling the spaces S defined by the insulating mold pattern 160a from being diffused to other layers. The second barrier layer 172 can be formed to a thickness of several to hundreds of A according to the width and depth of the spaces S. For example, the second barrier layer 172 may be formed to a thickness of approximately 5 to 150 Å. The second barrier layer 172 may be formed of Ta, TaN, TiN, TaSiN, TiSiN, WN, or a combination thereof by CVD or sputtering. The formation of the second barrier layer 172 is not essential and is optional and thus can be omitted.

The second conductive layer 174 can be formed for example, of a metal selected from the group consisting of Cu, W, and Al. For example, the second conductive layer 174 may be formed of Cu with a relatively low resistivity. The second conductive layer 174 may be formed by physical vapor deposition (PVD) or electroplating.

Alternatively, the second conductive layer 174 may be formed by a first process using PVD and a second process using electroplating. For example, in order to from the second conductive layer 174 formed of Cu, a first Cu layer may be formed by PVD on the second barrier layer 172 and a second Cu layer may be formed by electroplating using the first Cu layer as a seed layer. In this case, the first Cu layer initially provides a nucleation site for the subsequent electroplating, such that the second Cu layer can be uniformly formed on the first Cu layer through the electroplating. The first Cu layer may be formed to a thickness of approximately 100 to 500 Å. The second Cu layer is formed to a thickness great enough to completely fill the spaces S. For example, the second Cu layer can be formed to a thickness of approximately 1000 to 10000 Å.

Referring to FIG. 2K, upper portions of the second conductive layer 174 and the second barrier layer 172 are etched back or removed by CMP until the top surface of the insulating mold pattern 160a is exposed, to form a plurality of wiring lines 170a including a second barrier pattern 172a and a second conductive pattern 174a remaining in the spaces S defined by the insulating mold pattern 160a. The plurality of wiring lines 170a may correspond to the plurality of bit lines 30 of FIG. 1.

Accordingly, the etch mask pattern 132a and the insulating spacers 150a remain between two adjacent wiring lines 170a of the plurality of wiring lines 170a and between the plurality of wiring lines 170a and neighboring ones of the plurality of contact plugs 140a.

Since the etch mask pattern 132a and the insulating spacers 150a are present between the contact plugs 140a and the wiring lines 170a, a sufficient insulating margin is maintained between the plurality of wiring lines 170a formed on the contact plugs 140a between the contact plugs 140a. Accordingly, even when the fine mask pattern 162 is misaligned relative to the plurality of contact plugs 140a as shown in FIG. 2I, the bridge phenomenon due to a short-circuit that is an unwanted electrical connection between a wiring line and an adjacent contact plug other than a desired contact plug can be prevented.

FIGS. 3A and 3B are cross-sectional views illustrating a method of manufacturing a semiconductor device, according to another embodiment of the present invention. In more detail, FIGS. 3A and 3B correspond to cross-sectional views taken along section line II-II′ of FIG. 1. In FIGS. 3A and 3B, the same elements as those in FIGS. 2A through 2K are designated by the same reference numerals, and thus a detailed explanation thereof will not be given.

Referring to FIG. 3A, in the same way as described above with reference to FIGS. 2A through 2K, the etch mask pattern 132a, the contact plugs 140a, and the insulating spacers 150a are formed on the semiconductor substrate 100, and then a wiring layer 270 is formed on a resultant structure including the insulating spacers 150a. The wiring layer 270 includes a third barrier layer 272 and a third conductive layer 274.

For forming the wiring layer 270, the third barrier layer 272 is formed on the top surfaces of the contact plugs 140a which are exposed through the insulating spacers 150a, the sidewalls of the insulating spacers 150a, and the exposed surface of the etch mask pattern 132a, and then the third conductive layer 274 is formed on the third barrier layer 272.

For example, the third barrier layer 272 may be formed of Ta, TaN, TiN, TaSiN, TiSiN, WN, or a combination thereof by CVD or sputtering. The formation of the third barrier layer 272 is not essential, and thus may be omitted. The third conductive layer 274 can be formed, for example of a metal selected from the group consisting of W and Al. For example, the third barrier layer 272 may be formed of WN and the third conductive layer 274 may be formed of W.

Referring to FIG. 3B, the third conductive layer 274 and the third barrier layer 272 of the wiring layer 270 are sequentially etched using as an etch mask a fine mask pattern (not shown) that is formed by photolithography or a self-aligned double patterning process that enhances feature density by doubling a pitch of a pattern formed by photolithography, to form wiring lines 270a, each including a third barrier pattern 272a and a third conductive pattern 274a.

Accordingly, the etch mask pattern 132a and the insulating spacers 150a remain between two adjacent wiring lines 270a of the plurality of wiring lines 270a and between the plurality of wiring lines 270a and the plurality of contact plugs 140a.

Due to the etch mask pattern 132a and the insulating spacers 150a formed between the contact plugs 140a and the wiring lines 270a, a sufficient insulating margin is provided between the plurality of wiring lines 270a formed on the contact plugs 140a between the contact plugs 140a. Accordingly, even when the plurality of wiring lines 270a are misaligned with the plurality of contact plugs 140a as shown in FIG. 3B, a bridging phenomenon due to a short-circuit that is an unwanted electrical connection between a wiring line and an adjacent contact plug other than a desired contact plug can be prevented.

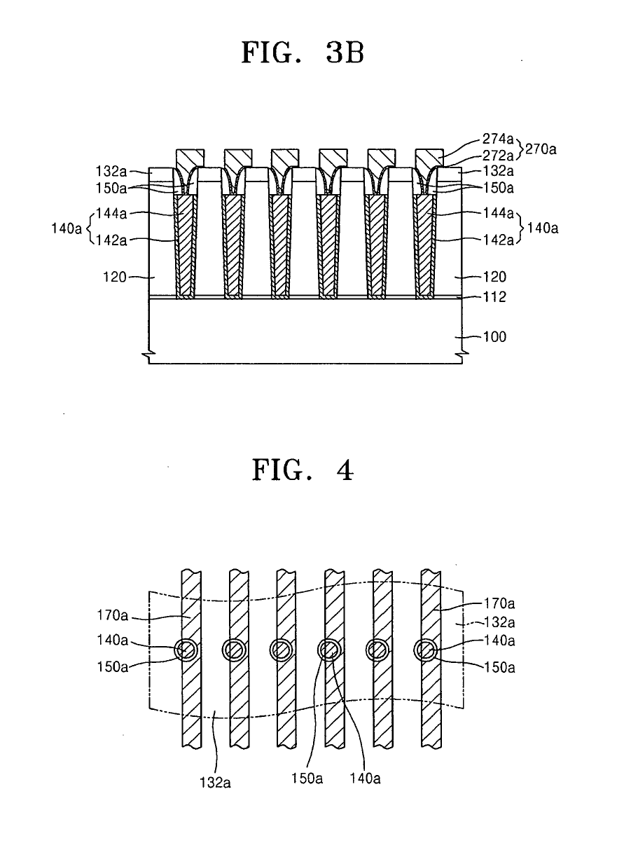

FIG. 4 is a plan layout illustrating the plurality of contact plugs 140a, the etch mask pattern 132a, the insulating spacers 150a, and the plurality of wiring lines 170a of the semiconductor device manufactured by the method of FIGS. 2A through 2K. Referring to FIG. 4, the etch mask pattern 132a and the insulating spacers 150a remain between two adjacent wiring lines 170a of the plurality of wiring lines 170a and between the plurality of wiring lines 170a and the plurality of contact plugs 140a. Accordingly, even if misalignment occurs between the plurality of contact plugs 140a and the plurality of wiring lines 170a while the plurality of wiring lines 170a are formed, a wiring line can be easily electrically connected to a desired contact plug, and a bridge phenomenon due to an unwanted short-circuit between the wiring line and a contact plug other than the desired contact plug can be prevented.

Since the etch mask pattern 132a, which remains between two adjacent wiring lines 170a of the plurality of wiring liens 170a, is formed of a material having a relatively high dielectric constant, for example, a silicon nitride, since the etch mask pattern 132a is formed under the plurality of wiring lines 170a to completely cover the top surface of the inter-layer insulating layer 120, the risk of forming a coupling capacitor due to the etch mask pattern 132a can be avoided even in a case where the interval between the two adjacent wiring lines 170a is reduced. In view of this, RC delay due to the etch mask pattern 132a remaining between the plurality of wiring lines 170a can be prevented.

Although not shown, a plan layout similar to that of FIG. 4 may be obtained from the semiconductor device manufactured by the method of FIGS. 3A and 3B, and thus the same effect as that of the semiconductor device manufactured by the method of FIGS. 2A through 2K can be achieved from the semiconductor device manufactured by the method of FIGS. 3A and 3B.

As described above, the etch mask pattern, which completely covers the top surface of the inter-layer insulating layer and the insulating spacers, which are formed on the top surfaces of the plurality of contact plugs to cover the sidewall of the etch mask pattern and the sidewall of the inter-layer insulating layer remain between two adjacent wiring lines of the plurality of wiring lines and between the plurality of wiring lines and the plurality of contact plugs. Accordingly, even if the plurality of contact plugs are misaligned with the plurality of wiring lines while the plurality of wiring lines are formed on the plurality of contact plugs to be respectively electrically connected to the plurality of contact plugs, a wiring line can be easily electrically connected to a desired contact plug, and a bridge phenomenon due to a short-circuit between the wiring lines and a contact plug other than the desired contact plug can be prevented.

Moreover, even though the etch mask pattern is formed of a material having a relatively high dielectric constant, since the etch mask pattern is formed under the plurality of wiring lines to entirely cover the top surface of the inter-layer insulating layer, the risk of forming a coupling capacitor due to the etch mask pattern can be avoided although an interval between the two adjacent wiring lines is reduced. Thus RC delay due to the etch mask pattern remaining between the plurality of wiring lines can be prevented.

While the present invention has been particularly shown and described with reference to exemplary embodiments thereof, it will be understood by one of ordinary skill in the art that various changes in form and details may be made therein without departing from the spirit and scope of the present invention as defined by the following claims.

1. A semiconductor device comprising:
a substrate comprising a plurality of conductive areas;
an inter-layer insulating layer on the substrate having a plurality of contact holes through which the conductive areas are exposed;
a first insulating layer covering the top surface of the inter-layer insulating layer;
a plurality of contact plugs respectively connected to the plurality of conductive areas through the plurality of contact holes, the plurality ofcontact plugs having top surfaces a distance from each of which to a top surface of the substrate is less than a distance from the top surface of the inter-layer insulating layer to the top surface of the substrate;
a plurality of ring-shaped insulating spacers covering inner sidewalls of the inter-layer insulating layer, inner sidewalls of the first insulating layer, and outer edge areas of top surfaces of the contact plugs so as to expose center areas of the top surfaces of the contact plugs in the contact holes; and
a plurality of wiring lines above the first insulating layer and on the insulating spacers and respectively electrically connected to the plurality of contact plugs.

2. The semiconductor device of claim 1, wherein each of the first insulating layer and the insulating spacers is formed of a material different than that of the inter-layer insulating layer.

3. The semiconductor device of claim 1, wherein the first insulating layer and the insulating spacers are formed of the same material, and each are formed of a material different than that of the inter-layer insulating layer.

4. The semiconductor device of claim 1, wherein the first insulating layer covers the top surface of the inter-layer insulating layer.

5. The semiconductor device of claim 1, wherein the conductive areas are active areas formed on the substrate.

6. The semiconductor device of claim 1, wherein the plurality of wiring lines are a plurality of bit lines that are repeatedly formed with a predetermined pitch and extend in parallel to one another.

7. The semiconductor device of claim 1, wherein the plurality of wiring lines comprise a metal.

8. The semiconductor device of claim 1, wherein the plurality of wiring lines comprise Cu.

9-20. (canceled)
